(19) United States
(12) Patent Application Publication
(10) Pub. No.: US 2026/0297377 A1
(43) Pub. Date: Oct. 1, 2026

(54) POLYMER AND COMPOSITION COMPRISING THE SAME

(71) Applicant: Merck Patent GmbH, Darmstadt (DE)

(72) Inventors: Niels Schulte, Kelkheim (DE); Ryo Sasaki, Shizuoka (JP); Atsuhiko Sato, Tokyo (JP); Kousuke Kabasawa, Shizuoka (JP)

(21) Appl. No.: 19/677,372

(22) Filed: May 14, 2026

Related U.S. Application Data
(63) Continuation of application No. PCT/EP2024/082101, filed on Nov. 13, 2024.

(30) Foreign Application Priority Data
Nov. 17, 2023 (JP) 2023-196173

(51) Int. Cl. C09D 183/16; C08G 77/62; H10P 14/60; H10P 14/68

(52) U.S. Cl. CPC C09D 183/16; C08G 77/62; H10P 14/6342; H10P 14/683

(57) ABSTRACT

A polymer includes a repeating unit (A) represented by the formula (1) disclosed herein and a repeating unit (B) represented by the formula (2) disclosed herein.

### CROSS REFERENCE TO RELATED APPLICATIONS

This application is a Continuation under 35 U.S.C. § 111 (a) of International Patent Application No. PCT/EP2024/082101 filed on Nov. 13, 2024, which claims priority to Japanese Patent Application No. 2023-196173 filed on Nov. 17, 2023, both of which are hereby incorporated by reference in their entirety.

### BACKGROUND OF THE INVENTION

### Technical Field

The present invention relates to a polymer having a specific structure. Further, the present invention relates to a composition comprising a polymer having a specific structure and a solvent. Furthermore, the present invention relates to a polymer having a specific structure, a composition comprising the same, and a method for manufacturing a cured film.

### Background Art

In the manufacture of electronic devices, especially semiconductor devices, interlayer insulating films are formed between transistor elements and bit lines, between bit lines and capacitors, between capacitors and metal wiring, between multiple metal wirings, and the like. Further, insulating materials are sometimes embedded in isolation trenches formed on the surface of a substrate, etc. Furthermore, after semiconductor devices are formed on the surface of a substrate, a coating layer is formed using a sealing material, and packaging is performed. Interlayer insulating films and coating layers are often formed from silicon-containing materials.

In order to form silicon-containing films such as silicon-based films, silicon nitride films, silicon carbide films and silicon carbonitride films, chemical vapor deposition method (CVD method), sol-gel method, and a method for applying a composition comprising a silicon-containing polymer and then heating it are used. Among these methods, the method for applying a composition and heating it to form a silicon-containing film is often used because it is a relatively simple method and has excellent embedding properties for narrow trenches. Examples of the silicon-containing polymer include polysilazane, polysiloxane, polycarbosilane, polysilane, and the like.

Polysilazane has the property of being converted to a siliceous substance by heating. Various technical problems have been investigated to be improved by modifying polysilazane itself or by combining a specific additive with a polysilazane-containing composition. For example, WO 2018/107138 A discloses a silicon-containing precursor compound having a hydrolyzable functional group such as N—C≡N.

### SUMMARY OF THE INVENTION

The present inventors thought that there are one or more problems that still need improvement with respect to compounds and compositions for forming cured films. Examples of these include the following:

The film shrinks when heated for curing; film thickness of the cured film is thin; time required for curing is long; peeling occurs due to film shrinkage generation of cracks cannot be suppressed; there is room for improvement in the yield of the cured film; the composition cannot be uniformly applied; insulation properties of the cured film are insufficient; electrical properties of the cured film are insufficient; flat band voltage of the cured film cannot be suppressed; chemical resistance of the cured film is insufficient; wet etching rate of the cured film is high; acid resistance of the cured film is insufficient; heat resistance of the cured film is insufficient; generation of voids in the cured film cannot be sufficiently suppressed; and adhesion to wiring materials, silica films, etc. is insufficient.

The polymer according to the present invention comprises a repeating unit (A) represented by the formula (1); and a repeating unit (B) represented by the formula (2).

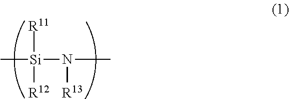

wherein
R¹¹ to R¹³ are each independently a single bond, H or C₁₋₁₀ alkyl.

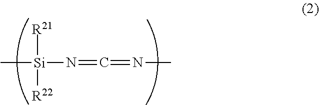

wherein
R²¹ and R²² are each independently a single bond, H, C₁₋₁₀ alkyl, —NR²³ or —N═C═N—; and
R²³ is H or C₁₋₁₀ alkyl.

The composition according to the present invention comprises the above-mentioned polymer, and a solvent.

The method for manufacturing a cured film according to the present invention comprises the following steps:
applying the above-mentioned composition above a substrate to form a coating film; and
heating the coating film.

The cured film according to the present invention is one that is obtained by the above-mentioned method.

The electronic device according to the present invention comprises the above-mentioned cured film.

The method for manufacturing an electronic device according to the present invention comprises the above-mentioned method.

The present invention relates to the use of the above-mentioned composition for forming a cured film above a substrate.

The present invention may provide one or more of the following effects:
Film shrinkage when heated for curing is suppressed; film thickness of the cured film is sufficient; time required for curing is suppressed; occurrence of peeling due to film shrinkage is suppressed; occurrence of cracks is suppressed; yield of the cured film is improved; the composition can be sufficiently uniformly applied; insulation properties of the cured film are sufficient; electrical properties of the cured film are sufficient; flat band voltage of the cured film can be suppressed; chemical resistance of the cured film is sufficient; wet etching rate of the cured film is sufficiently low; acid resistance of the cured film is sufficient; heat resistance of the cured film is sufficient; generation of voids in the cured film can be sufficiently suppressed; and adhesion to wiring materials, silica films, etc. is sufficient.

### BRIEF DESCRIPTION OF THE DRAWINGS

FIG. 1 is an FTIR spectrum of the polymer according to the present invention.

FIG. 2 is a ¹³C-NMR spectrum of the polymer according to the present invention.

### DETAILED DESCRIPTION OF THE INVENTION

### Definitions

Unless otherwise specified in the present specification, the definitions and examples described in this paragraph are followed.

The singular form includes the plural form and “one” or “that” means “at least one”. An element of a concept can be expressed by a plurality of species, and when the amount (for example, mass % or mol %) is described, it means sum of the plurality of species.

“And/or” includes a combination of all elements and also includes single use of the element.

When a numerical range is indicated using “to” or “-”, it includes both endpoints and units thereof are common. For example, 5 to 25 mol % means 5 mol % or more and 25 mol % or less.

The descriptions such as “C_{x-y}”, “Cₓ-C_{y}” and “Cₓ” mean the number of carbons in a molecule or substituent. For example, C₁₋₆ alkyl means an alkyl chain having 1 or more and 6 or less carbons (methyl, ethyl, propyl, butyl, pentyl, hexyl, etc.).

The groups, such as alkyl, alkylene and alkoxy can be any structure containing linear, branched or cyclic structure. The alkyl group means a group obtained by removing any one hydrogen from a saturated hydrocarbon, and the alkylene group means a group obtained by removing any two hydrogen from a saturated hydrocarbon.

When a polymer has a plural types of repeating units, these repeating units copolymerize. This copolymerization may be any of alternating copolymerization, random copolymerization, block copolymerization, graft copolymerization, or a mixture thereof. When a polymer or resin is represented by a structural formula, n, m or the like that is attached next to parentheses indicate the number of repetitions.

Celsius is used as the temperature unit. For example, 20 degrees means 20 degrees Celsius.

The additive refers to a compound itself having a function thereof (for example, in the case of a base generator, a compound itself that generates a base). An embodiment in which the compound is dissolved or dispersed in a solvent and added to a composition is also possible. As one embodiment of the present invention, it is preferable that such a solvent is contained in the composition according to the present invention as the solvent (G) or another component.

Embodiments according to the present invention are described below in detail.

### Polymer

The polymer according to the present invention comprises
a repeating unit (A) represented by the formula (1) (hereinafter sometimes referred to as repeating unit A); and
a repeating unit (B) represented by the formula (2) (hereinafter sometimes referred to as repeating unit B).

The polymer according to the present invention can also comprise repeating units other than the repeating units A and B. When the total number of the repeating unit A is taken as n_{A}, the total number of the repeating unit B is taken as n_{B}, and the total number of all repeating units comprised in the polymer according to the present invention is taken as nₜₒₜₐₗ, (n_{A}+n_{B})/nₜₒₜₐₗ is preferably 80 to 100%, more preferably 90 to 100%, and further preferably 95 to 100%.

It is one preferable embodiment of the present invention that no repeating units other than the repeating units A and B are comprised in the polymer ((n_{A}+n_{B})/nₜₒₜₐₗ=100%).

The formula (1) is as follows:

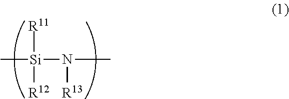

wherein
R¹¹ to R¹³ are each independently a single bond, H or C₁₋₁₀ alkyl, preferably a single bond, H, C₁₋₁₀ linear alkyl, C₁₋₁₀ branched alkyl or C₁₋₁₀ alkyl containing a ring structure, more preferably a single bond, H, C₁₋₅ linear alkyl or C₁₋₅ branched alkyl, further preferably a single bond, H, or C₁₋₅ linear alkyl, and further more preferably a single bond or H.

In a preferable embodiment, the polymer according to the present invention comprises 20 or more, preferably 20 to 350, and more preferably 50 to 300, repeating units selected from the group consisting of the following formulae (1-i) to (1-vi).

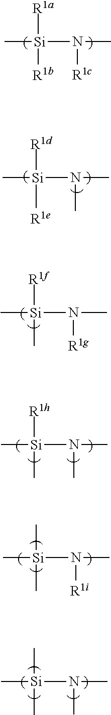

wherein
R^{1a} to R¹ⁱ are each independently a single bond, H or C₁₋₁₀ alkyl, preferably H, C₁₋₁₀ linear alkyl, C₁₋₁₀ branched alkyl or C₁₋₁₀ alkyl containing a ring structure, more preferably H, C₁₋₅ linear alkyl or C₁₋₅ branched alkyl, further preferably H or C₁₋₅ linear alkyl, and furthermore preferably H.

The formula (2) is as follows:

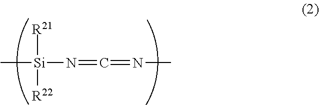

wherein
R²¹ and R²² are each independently a single bond, H, C₁₋₁₀ alkyl, —NR²³— or —N═C═N—, preferably a single bond, H, C₁₋₁₀ linear alkyl, C₁₋₁₀ branched alkyl, C₁₋₁₀ alkyl containing a ring structure, —NR²³— or —N═C═N—, more preferably a single bond, H, C₁₋₅ linear alkyl or C₁₋₅ branched alkyl, further preferably a single bond, H or C₁₋₅ linear alkyl, and further more preferably a single bond or H. When R²¹ and R²² are divalent groups, they are bonded to another repeating unit.
R²³ is H or C₁₋₁₀ alkyl, preferably H, C₁₋₁₀ linear alkyl, C₁₋₁₀ branched alkyl or C₁₋₁₀ alkyl containing a ring structure, more preferably H, C₁₋₅ linear alkyl or C₁₋₅ branched alkyl, further preferably H or C₁₋₅ linear alkyl, and furthermore preferably H.

Examples of partial structure of the polymer according to the present invention are given below.

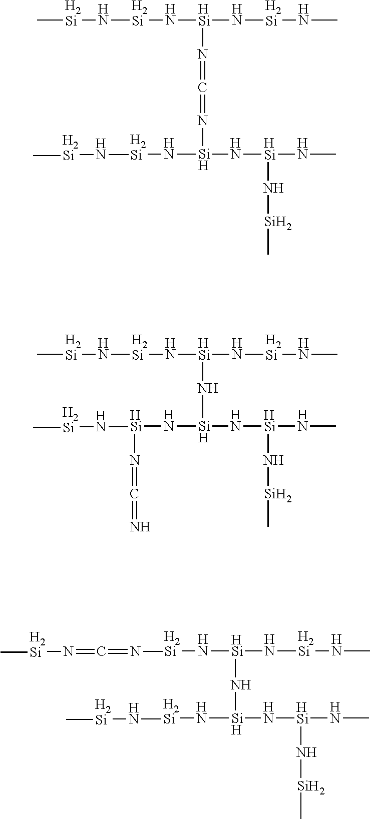

As an example, how to read the following partial structure is described in detail with reference to the formulae (1) and (2).

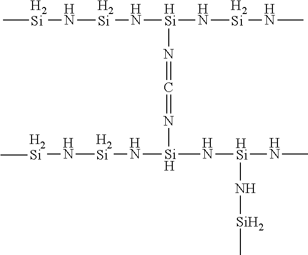

The above partial structure can be read that the repeating units based on the formula (1) in which R¹¹ to R¹³ are H, repeating units based on the formula (1) in which R¹¹ and R¹³ are H and R¹² is a single bond, and repeating units based on the formula (2) in which R²¹ is —N═C═N— and R²² is H are mixed.

In the polymer according to the present invention, the average ratio of the total number of —N═C═N— structures contained in one molecule to the total number of Si atoms contained in one molecule is preferably 0.2 or less, more preferably 0.001 to 0.1, and further preferably 0.002 to 0.05.

Although the method for calculating the average ratio of the total number of —N═C═N— structures contained in one molecule to the total number of Si atoms contained in one molecule is not particularly limited, it can be calculated, for example, by the following method.

The composition comprising the polymer according to the present invention is applied above a flat surface such as a wafer surface to form a film. The number of Si atoms and the number of C atoms derived from —N═C═N— are quantified at any number of measurement points on the film surface by secondary ion mass spectrometry (SIMS). The ratio of the number of Si atoms quantified at each measurement point to the number of C atoms derived from —N═C═N— quantified at each measurement point is calculated, and the average of the calculated ratios is obtained, so that the total number of Si atoms contained in one molecule to the average ratio of the total number of —N═C═N— structures contained in one molecule can be calculated.

The weight average molecular weight of the polymer according to the present invention is preferably 2,500 to 20,000, more preferably 3,000 to 19,000, and further preferably 4,000 to 18,000. In the present invention, the weight average molecular weight is a number average molecular weight in terms of polystyrene, and can be measured by the gel permeation chromatography based on polystyrene.

Although not to be bound by theory, it can be thought that when the weight average molecular weight of the polymer according to the present invention is 2,500 or more, mass reduction of the film can be further suppressed when the coating film of the composition according to the present invention is heated and cured. It can be thought that this makes it possible to further suppress the film shrinkage. Furthermore, although not to be bound by theory, it can be thought that when the weight average molecular weight of the polymer according to the present invention is 20,000 or less, formation of microgels in the coating film of the composition according to the present invention can be further suppressed. It can be thought that this makes it possible to further suppress the generation of voids in the cured film.

The cured film formed using the polymer according to the present invention is sufficient in chemical resistance, for example resistance to hydrofluoric acid. The cured film formed using the polymer according to the present invention can suppress the flat band voltage. Although not to be bound by theory, it can be thought that this is due to the following reasons. It can be presumed that the repeating unit (B) of the polymer according to the present invention is more susceptible to hydrolysis than the repeating unit (A). Therefore, for example, it can be thought that compared to a polymer composed only of the repeating unit (A), the polymer according to the present invention has improved susceptibility to hydrolysis as a whole. As a result, it can be thought that the polymer according to the present invention is relatively more susceptible to conversion to SiO₂ by heating, which leads to improved chemical resistance of the formed cured film.

### Method for Manufacturing a Polymer

Although the method for manufacturing a polymer according to the present invention is not particularly limited, it can be manufactured by reacting a compound comprising the above formula (1) with a cyanamide derivative.

The compound comprising the formula (1) preferably comprises 20 or more, preferably 20 to 350, more preferably 50 to 300 repeating units selected from the group consisting of the above formulae (1-i) to (1-vi). In this case, it is preferable that each repeating unit is directly bonded without intervening any repeating unit other than (1-i) to (1-vi).

The compound comprising the formula (1) is preferably polysilazane, more preferably perhydropolysilazane (hereinafter referred to as PHPS). PHPS is a silicon-containing polymer that contains Si—N bonds as repeating units and is composed only of Si, N and H. In this PHPS, all elements bonded to Si and N, except for Si—N bonds, are H, and other elements such as carbon and oxygen are substantially absent. The simplest structure of perhydropolysilazane is a linear structure having the following repeating unit:

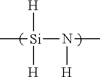

The structure of PHPS is not limited as long as it is a silicon-containing polymer containing Si—N bonds as repeating units and consisting only of Si, N and H, and PHPS can have various structures other than those exemplified above. PHPS is preferably one having a cyclic structure or a crosslinked structure, particularly a crosslinked structure. The terminal group of perhydropolysilazane is preferably —NH₂ or —SiH₃.

Examples of the cyanamide derivative include cyanamide, dicyandiamide, guanidine, biguanide, urea, cyanourea, guanylurea, melamine and cyanomelamine, and cyanamide is preferable.

### Composition

The composition according to the present invention comprises
the above polymer; and
a solvent.

### Solvent

The solvent is preferably at least one selected from the group consisting of aromatic compounds, saturated hydrocarbon compounds, unsaturated hydrocarbon compounds, ether compounds, ester compounds and ketone compounds.

Exemplified embodiment thereof include the following:
aromatic compounds (for example, benzene, toluene, xylene, ethylbenzene, diethylbenzene, trimethylbenzene and triethylbenzene);
saturated hydrocarbon compounds (for example, decahydro-naphthalene, dipentene, n-pentane, i-pentane, n-hexane, i-hexane, n-heptane, i-heptane, n-octane, i-octane, n-nonane, i-nonane, n-decane, ethylcyclohexane, methylcyclohexane, cyclohexane and p-menthane);
unsaturated hydrocarbons (for example, cyclohexene);
ether compounds (for example, dipropyl ether, dibutyl ether, anisole and cyclopentyl methyl ether);
ester compounds (for example, n-butyl acetate, i-butyl acetate, n-amyl acetate and i-amyl acetate); and
ketone compounds (for example, methyl isobutyl ketone (MIBK)).

These can be used alone or in combination. Preferable solvents are xylene, dibutyl ether and anisole.

The content of the solvent is preferably 50 to 99 mass %, more preferably 60 to 90 mass %, based on the total mass of the composition.

The composition according to the present invention can be combined with additional components as necessary. The content of the components other than the polymer and solvent in the entire composition is preferably 10 mass % or less, more preferably 5 mass % or less, further preferably 1 mass % or less, and further more preferably 0 mass % (an embodiment in which none is included), based on the total mass of the composition.

In addition, although the composition according to the present invention can comprise any polymer other than the above-mentioned polymer according to the present invention (hereinafter sometimes referred to as other polymer), the content of the other polymer is preferably 10 mass % or less, more preferably 5 mass % or less, and further preferably 0 mass % (an embodiment in which none is included), based on the total mass of the polymer according to the present invention.

### Optional Components

Examples of the optional component include catalysts, adhesion promoters, corrosion-resistant additives, crosslinking agents, dispersants, fillers, functional dyes (for example, those that provide functional effects such as electrical conductivity, thermal conductivity and magnetic properties), nanoparticles, optical dyes (for example, those that provide optical effects such as color tone, refractive index and pearlescent effect), particles that reduce thermal expansion, polymerization initiators, polymerization inhibitors, primers, rheology modifiers (for example, thickeners), bond enhancers, surfactants, anti-foaming agents and viscosity modifiers.

By the addition of a catalyst, curing of the composition according to the present invention can be accelerated. Examples of useful catalyst are Lewis acids such as boron alkyl, aluminum alkyl, tin alkyl, zinc alkyl, aryl or carboxylate, Bronsted acids such as carboxylic acid, bases such as primary, secondary or tertiary amine or phosphazene, or metal salts such as Pd, Pt, Al, B, Sn or Zn salt of carboxylate, acetylacetonate or alkoxylate.

The nanoparticle can be selected from nitrides, titanates, diamond, oxides, sulfides, sulfites, sulfates, silicates and carbides, which can be optionally surface-modified with a capping agent. The particle size of the nanoparticle can be, for example, 1 to 100 nm, 1 to 50 nm or 1 to 25 nm. The particle size can be measured by any standard method known to those skilled in the art.

As the polymerization initiator, those generate acids, bases or radicals by radiation, and those generates acids, bases or radicals by heat can be used. Photo radical generators are more preferable in terms of shortening the process and reducing costs, since the reaction starts immediately after irradiation and the reheating process performed after irradiation and before the development process can be omitted.

As the polymerization inhibitor, ultraviolet absorbers; and nitrones, nitrogen oxide radicals, hydroquinone, catechol, phenothiazine, phenoxazine, hindered amines and derivatives thereof can be used. Specifically, methylhydroquinone, catechol, 4-t-butylcatechol, 3-methoxycatechol, phenothiazine, chlorpromazine, phenoxazine, TINUVIN 144, 292 and 5100 (BASF) as hindered amines, TINUVIN 326, 328, 384-2, 400 and 477 (BASF) as ultraviolet absorbers, and the like can be used.

The photo radical generator can improve resolution by strengthening the pattern shape and increasing the contrast of development. The photo radical generator that can be used in the present invention is a photo radical generator that releases radicals when irradiated with radiation. Here, examples of the radiation include visible light, ultraviolet ray, infrared ray, X-ray, electron beam, α-ray, γ-rays, and the like.

Examples of the photo radical generator that can be used include azo-based, peroxide-based, acylphosphine oxide-based, alkylphenone-based, oxime ester-based and titanocene-based initiators. Among them, alkylphenone-based, acylphosphine oxide-based and oxime ester-based initiators are preferable, and 2,2-dimethoxy-1,2-diphenylethan-1-one, 1-hydroxy-cyclohexyl phenyl ketone, 2-hydroxy-2-methyl-1-phenylpropan-1-one, 1-[4-(2-hydroxyethoxy)phenyl]-2-hydroxy-2-methyl-1-propan-1-one, 2-hydroxy-1-{4-[4-(2-hydroxy-2-methylpropionyl)-benzyl]phenyl}-2-methylpropan-1-one, 2-methyl-1-(4-methylthiophenyl)-2-morpholinopropan-1-one, 2-benzyl-2-dimethylamino-1-(4-morpholinophenyl)-1-butanone, 2-(dimethylamino)-2-[(4-methylphenyl)methyl]-1-[4-(4-morpholinyl)-phenyl]-1-butanone, 2,4,6-trimethylbenzoyldiphenylphosphine oxide, bis(2,4,6-trimethylbenzoyl)-phenyl-phosphine oxide, 1,2-octanedione, 1-[4-(phenylthio)-2-(O-benzoyloxime)], ethanone, 1-[9-ethyl-6-(2-methylbenzoyl)-9H-carbazol-3-yl]-1-(O-acetyloxime), and the like can be used.

The bond enhancer has the effect of preventing the coating film from peeling off from the substrate due to the stress applied when the composition according to the present invention is applied above a substrate to form a coating film and then cured by heating. As the bond enhancer, imidazole, silane coupling agents, and the like are preferable. As the imidazole, 2-hydroxybenzimidazole, 2-hydroxyethylbenzimidazole, benzimidazole, 2-hydroxyimidazole, imidazole, 2-mercaptoimidazole, 2-aminoimidazole, and the like can be used.

As the silane coupling agent, epoxy silane coupling agents, amino silane coupling agents, mercapto silane coupling agents, and the like can be used. Specifically, 3-glycidoxypropyltrimethoxysilane, 3-glycidoxypropyl-triethoxysilane, N-2-(aminoethyl)-3-aminopropyltri-methoxysilane, N-2-(aminoethyl)-3-aminopropyltri-ethoxysilane, 3-aminopropyltrimethoxysilane, 3-aminopropyltriethoxysilane, 3-ureidopropyltriethoxysilane, 3-chloropropyltriethoxysilane, 3-mercaptopropyltri-methoxysilane, 3-isocyanatopropyltriethoxysilane, and the like can be used.

Furthermore, as the silane coupling agent, a silane compound and a siloxane compound having an acid group, or the same kind of compound can be used. Examples of the acid group include a carboxyl group, an acid anhydride group and a phenolic hydroxyl group.

As the anti-foaming agent, alcohols (C₁₋₁₈), higher fatty acids such as oleic acid and stearic acid, higher fatty acid esters such as glycerin monolaurate, polyethers such as polyethylene glycol and polypropylene glycol, silicone compounds such as dimethyl silicone oil, alkyl-modified silicone oil and fluorosilicone oil, and the like can be used.

The use of a surfactant is preferable because it can improve the coatability. Examples of the surfactant that can be used in the composition according to the present invention include nonionic surfactants, anionic surfactants and amphoteric surfactants.

Examples of the nonionic surfactant include, polyoxyethylene alkyl ethers, such as polyoxyethylene lauryl ether, polyoxyethylene oleyl ether and polyoxyethylene cetyl ether; polyoxyethylene fatty acid diester; polyoxyethylene fatty acid monoester; polyoxyethylene polyoxypropylene block polymer; acetylene alcohol; acetylene glycol; acetylene alcohol derivatives, such as polyethoxylate of acetylene alcohol; acetylene glycol derivatives, such as polyethoxylate of acetylene glycol; fluorine-containing surfactants, such as FLUORAD (3M Japan), MEGAFACE (DIC), SURFLON (AGC); or organosiloxane surfactants, such as KP341 (Shin-Etsu Chemical). Examples of the above-mentioned acetylene glycol include 3-methyl-1-butyne-3-ol, 3-methyl-1-pentyn-3-ol, 3,6-dimethyl-4-octyne-3,6-diol, 2,4,7,9-tetramethyl-5-decyne-4,7-diol, 3,5-dimethyl-1-hexyne-3-ol, 2,5-dimethyl-3-hexyne-2,5-diol, 2,5-dimethyl-2,5-hexanediol, and the like.

Examples of the anionic surfactant include ammonium salt or organic amine salt of alkyl diphenyl ether disulfonic acid, ammonium salt or organic amine salt of alkyl diphenyl ether sulfonic acid, ammonium salt or organic amine salt of alkyl benzene sulfonic acid, ammonium salt or organic amine salt of polyoxyethylene alkyl ether sulfuric acid, ammonium salt or organic amine salt of alkyl sulfuric acid, and the like.

Examples of the amphoteric surfactant include 2-alkyl-N-carboxymethyl-N-hydroxyethyl imidazolium betaine, lauric acid amide propyl hydroxysulfone betaine, and the like.

These surfactants can be used alone or in combination of two or more types. The compounding ratio is usually 50 to 10,000 ppm, preferably 100 to 5,000 ppm, based on the total mass of the composition.

### Method for Manufacturing a Cured Film

The method for manufacturing a cured film according to the present invention comprises the following steps:
applying the composition according to the present invention above a substrate to form a coating film; and
heating the coating film.

In the present invention, “above a substrate” includes the case where the composition is applied in contact with and above a substrate and the case where the composition is applied above a substrate via one or more interlayers.

The present invention relates to the use of the composition according to the present invention for forming a cured film above a substrate.

The method for applying a composition above the surface of a substrate can be freely selected from conventional methods, such as spin coating, dipping, spraying, transfer coating, roll coating, bar coating, brush coating, doctor coating, flow coating, and slit coating. The substrate above which the composition is applied can be a suitable substrate, such as a silicon substrate, a glass substrate or a resin film. These substrates can have various semiconductor elements formed thereon, if necessary. When the substrate is a film, gravure coating can also be used. If desired, a separate drying step can be provided after the coating. Further, if necessary, the coating step can be repeated two or more times to obtain a coating film having a desired thickness.

After forming a coating film of the composition according to the present invention, the coating film can be subjected to prebaking (heat treatment) to dry the coating film and reduce the amount of remaining solvent. The prebaking step can be performed in an oxidizing or non-oxidizing atmosphere, preferably at a temperature of 80 to 300° C., for 10 to 300 seconds using a hot plate, or for 1 to 30 minutes using a clean oven.

Then, the coating film, which has been prebaked as necessary, is heated to form a cured film. This heating is preferably performed in an oxidizing atmosphere.

The heating is preferably performed in a temperature range of 200 to 700° C., more preferably 300 to 600° C.

An oxidizing atmosphere means that when the total pressure is 101 kPa, the oxygen partial pressure is 20 to 101 kPa, preferably 40 to 101 kPa, and more preferably, the water vapor partial pressure of 1.5 to 80 kPa is included.

When heating at high temperature (for example, temperature exceeding 600° C.) in an atmosphere containing water vapor, there may be concerns about adverse effects on other elements, such as electronic devices, that are exposed to the heat treatment at the same time. In such cases, this heating process can be divided into two or more stages (more preferably three or more stages). For example, heating can be first performed at a low temperature (for example, temperature range of 200 to 400° C.) in an atmosphere containing water vapor, then heating is performed at a relatively low temperature (for example, temperature range of 300 to 600° C.) in an atmosphere containing water vapor, and then heating is performed at a higher temperature (for example, temperature range of 400 to 1,000° C.) in an atmosphere containing no water vapor.

Any gas can be used as the component other than water vapor in the atmosphere containing water vapor (hereinafter, sometimes referred to as dilution gas), and examples of such gas include air, oxygen, nitrogen, nitrogen oxide, ozone, helium and argon. Considering the film quality of the silicon-containing film, it is preferable to use oxygen as the dilution gas.

Although the temperature-raising rate to the target temperature and the temperature-lowering rate during heating are not particularly limited, it can generally be in the range of 1 to 100° C./min. There is also no particular limit to the heating retention time after the target temperature is reached, and can generally be in the range of 1 minute to 10 hours.

The film thickness of the cured film is preferably 100 to 3,000 nm, and more preferably 200 to 2,500 nm.

For the cured film according to the present invention, the film shrinkage is suppressed and it has excellent chemical resistance.

The cured film according to the present invention can suppress the flat band voltage. Specifically, an average absolute value of flat band voltage measured at five points using a mercury CV measuring device is preferably 0.1 to 4.0 V, more preferably 0.5 to 3.5 V, and further preferably 1.0 to 3.0 V, provided that the five points divide the diameter of the substrate into six equal parts.

The method for manufacturing an electronic device according to the present invention comprises the above manufacturing method. Preferably, the electronic device according to the present invention is a semiconductor device, a solar cell chip, an organic light-emitting diode or an inorganic light-emitting diode. One preferable embodiment of the electronic device of the present invention is a semiconductor device.

### EXAMPLES

The present invention is described below with reference to Examples. These Examples are for the purpose of explanation and are not intended to limit the scope of the present invention.

In the following examples, the number average molecular weight (Mn) and weight average molecular weight (Mw) are measured by the gel permeation chromatography (GPC) based on polystyrene. GPC measurement is performed using Waters ACQUITY APC System (Nihon Waters) and Shodex GPC HK-401 and Shodex GPC HK-404L columns (Shoko Science). The measurement is performed using monodisperse polystyrene as the standard sample and tetrahydrofuran as the eluent, under measurement conditions of a flow rate of 0.5 mL/min and a column temperature of 40° C., and Mn and Mw are calculated as the relative molecular weight to the standard sample.

### Synthesis of Polysilazane Intermediate A

After replacing the inside of a 10 L reaction vessel equipped with a cooling condenser, a mechanical stirrer and a temperature control device with dry nitrogen, 7,500 mL of dry pyridine is added to the reaction vessel and cooled to −3° C. Then, 500 g of dichlorosilane is added, and a white solid product (SiH₂Cl₂·2C₅H₅N) is generated. After confirming that the reaction mixture becomes −3° C. or below, 350 g of ammonia is slowly blown into it while stirring. This is stirred for 30 minutes, and dry nitrogen is blown into the liquid layer for 30 minutes to remove excess ammonia. The resulting slurry-like product is filtered under pressure using a 0.2 μm polytetrafluoroethylene filter under a dry nitrogen atmosphere to obtain 6,000 mL of filtrate. 3,000 mL of dry xylene is added, and the pyridine is distilled off using an evaporator. When concentrated, a 39.8 mass % xylene solution of polysilazane is obtained. When the Mn of the obtained polysilazane is measured by GPC, it is 1,070 in terms of polystyrene. The polysilazane obtained is hereinafter referred to as polysilazane intermediate A.

### Synthesis of Polymer A

In a 500 mL three-neck flask equipped with a magnetic stirrer bar, a nitrogen inlet and a reflux condenser, 51 g of a 42 mass % xylene solution of polysilazane intermediate A and 135 g of dry pyridine are added. A solution of a mixture of 0.10 g of cyanamide as a cyanamide derivative and 20 g of pyridine is added to this. Dry xylene is further added so that the content of polysilazane intermediate A becomes 10 mass % based on the entire reaction solution to prepare a reaction solution. While stirring, dry nitrogen is blown into this at room temperature for 30 minutes (100 mL/min). After that, it is heated at 110° C. for 7 hours and concentrated at 40° C. to obtain a 40 mass % solution of polymer A. The Mw of the obtained polymer A is 6,200.

### Synthesis of Polymer B and C

Polymer B and C solutions are obtained in the same manner as the synthesis of the polymer A, except that the compounding amount of C derivative added and the composition ratio of the solvent are changed as shown in Table 1. Each Mw is shown in Table 1.

TABLE 1

| | Cyanamide derivative | | | | |
|---|---|---|---|---|---|
| | | | Mole ratio | | |
| | | | of the | | |
| | | | compound | | |
| | | | to the | | |
| | | | polysilazane | Solvent | |
| | | Amount | intermediate | xylene/ | |
| | Compound | added | A | pyridine | Mw |
| Polymer A | Cyanamide | 0.10 g | 0.12 | 20/80 | 6,200 |
| Polymer B | Cyanamide | 0.10 g | 0.12 | 17/83 | 17,600 |
| Polymer C | Cyanamide | 0.80 g | 0.95 | 30/70 | 9,700 |
| Polysilazane Z | — | — | — | — | 8,300 |

### Synthesis of Polysilazane Z

After replacing the inside of a 10 L reaction vessel equipped with a cooling condenser, a mechanical stirrer and a temperature control device with dry nitrogen, 4,710 g of dry pyridine, 150 g of dry xylene and 1,650 g of the 39.8 mass % solution of polysilazane intermediate A obtained above are added and stirred to become homogenous while bubbling with dry nitrogen at 0.5 L/min. Subsequently, a modification reaction is carried out at 110° C. for 10 hours to obtain polysilazane Z. The pyridine is distilled off to obtain a polysilazane Z solution. The polysilazane Z is a perhydropolysilazane with an Mw of 8,300.

By the measurements of infrared absorption spectrum using FTIR6100 (JASCO), and ¹³C-NMR, it is understood that polymer A, B and C have a structure in which —N═C═N— is bonded to the Si of the polysilazane.

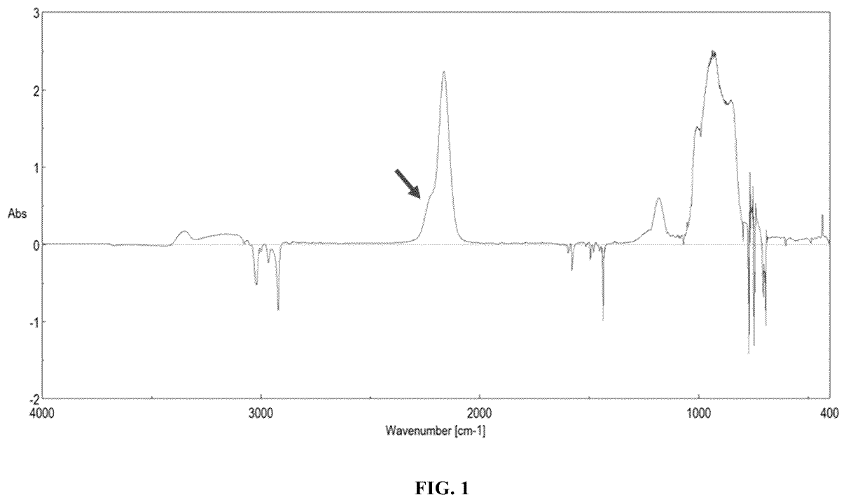

FIG. 1 shows the FTIR spectrum of the polymer C, where a peak at around 2,220 cm-1 assigned to —N═C═N— is confirmed.

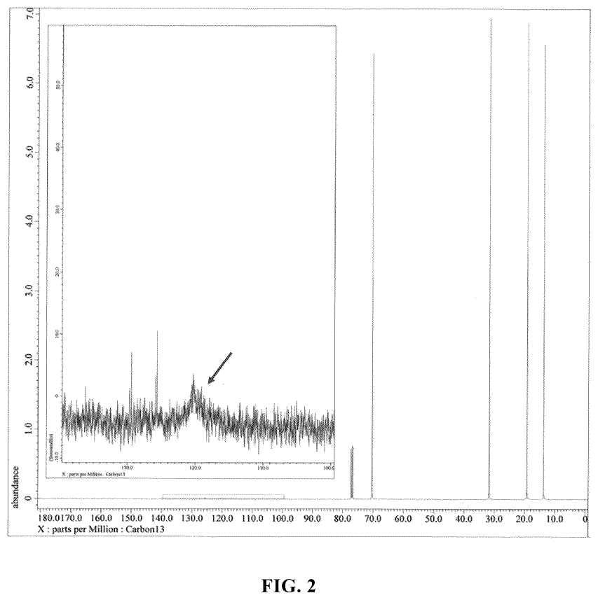

FIG. 2 shows the ¹³C-NMR spectrum of the polymer C, where a new peak at around 121 ppm assigned to —N═C═N— is confirmed, indicating the formation of —N═C═N—.

### Example 1

The composition of Example 1 is prepared by adding and mixing the polymer A synthesized above with dibutyl ether so that the concentration of the polymer A becomes 19 mass %.

The composition of Example 1 is applied above a 4-inch Si substrate that is pre-wetted with dibutyl ether, using a spin coater (1HDX2, Mikasa) to form a coating film. The resulting coating film is heated (baked) on a hot plate at 150° C. for 3 minutes. The film thickness (film thickness after baking) is measured to be 588 nm. The baked coating film is heated (cured) at 400° C. for 30 minutes in a water vapor atmosphere, cured at 1,000° C. for 30 minutes, and further heated (annealed) at 1,000° C. for 30 minutes in a nitrogen atmosphere to obtain a cured film of Example 1. The film thickness (film thickness after annealing) is 466 nm.

The film thickness is measured at 17 points on the diameter of the substrate using a spectroscopic ellipsometer (J.A. Woollam M-44), and the average value is obtained.

The flat band voltage (Vfb) is measured at 5 points on the diameter of the substrate with the cured film using a mercury CV measuring device (Semilab MCV530), and the average value is obtained.

The relative wet etching rate (rWER) to the thermal oxide film is measured using a spectroscopic ellipsometry (J.A. Woollam M-44) based on the thermal oxide film. For the measurement, a thermal oxide film is used as the standard sample, and the substrate with the cured film is immersed in a 0.5 mass % aqueous solution of hydrofluoric acid for 30 minutes. The film thickness is measured before and after immersion to obtain the wet etching rate per minute, and the rWER for the standard sample is then calculated.

### Examples 2 and 3, and Comparative Example 1

The cured films of Examples 2 and 3, and Comparative Example 1 are obtained in the same manner as in Example 1, except that the polymer used in the composition (in the case of Comparative Example 1, it is polysilazane Z) and the content thereof are changed as shown in Table 2. The film thickness, Vfb and rWER are also measured in the same manner, and the results obtained are shown in Table 2.

TABLE 2
Table 2

| | | | Concentration of | Film thickness | Film thickness | | |
|---|---|---|---|---|---|---|---|
| | | | the polymer A | after baking | after annealing | Vfb | |
| | Polymer | Solvent | (mass %) | (nm) | (nm) | (V) | rWER |
| Example 1 | Polymer A | Dibutyl ether | 19 | 588 | 466 | −2.1 | 0.91 |
| Example 2 | Polymer B | Dibutyl ether | 18 | 584 | 462 | −3.5 | 0.92 |
| Example 3 | Polymer C | Dibutyl ether | 18 | 597 | 449 | −2.3 | 0.92 |
| Comparative | Polysilazane Z | Dibutyl ether | 18 | 595 | 490 | −4.1 | 1.00 |
| Example 1 | | | | | | | |

1. A polymer comprising a repeating unit (A) represented by the formula (1) and a repeating unit (B) represented by the formula (2): 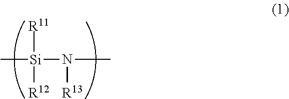
wherein
R¹¹ to R¹³ are each independently a single bond, H or C₁₋₁₀ alkyl, 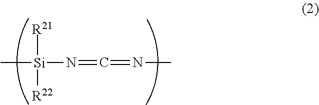
wherein
R²¹ and R²² are each independently a single bond, H, C₁₋₁₀ alkyl, —NR²³— or —N═C═N—; and
R²³ is H or C₁₋₁₀ alkyl.

2. The polymer according to claim 1, wherein a weight average molecular weight of the polymer in terms of polystyrene is in the range from 2,500 to 20,000 as measured by the gel permeation chromatography.

3. A composition comprising the polymer according to claim 1, and a solvent.

4. A method for manufacturing a cured film comprising the following steps:
applying the composition according to claim 3 to a substrate to form a coating film; and
heating the coating film.

5. The method for manufacturing a cured film according to claim 4, wherein the heating is performed in an oxidizing atmosphere.

6. A cured film obtained by the method according to claim 4.

7. The cured film according to claim 6, wherein an average absolute value of flat band voltage measured at five points using a mercury CV measuring device is 4.0 V or less,
provided that the five points divide the diameter of the substrate into six equal parts.

8. An electronic device comprising the cured film according to claim 6.

9. A method for manufacturing an electronic device, comprising the method according to claim 4.
